(19) United States
(12) Patent Application Publication
(10) Pub. No.: US 2019/0013062 A1
(43) Pub. Date: Jan. 10, 2019

(54) SELECTIVE REFRESH MECHANISM FOR DRAM

(71) Applicant: QUALCOMM Incorporated, San Diego, CA (US)

(72) Inventors: Francois Ibrahim ATALLAH, Raleigh, NC (US); Gregory Michael WRIGHT, Chapel Hill, NC (US); Shivam PRIYADARSHI, Morrisville, NC (US); Garrett Michael DRAPALA, Cary, NC (US); Harold Wade CAIN, III, Raleigh, NC (US); Erik HEDBERG, Durham, NC (US)

(21) Appl. No.: 15/644,737

(22) Filed: Jul. 7, 2017

(51) Int. Cl. G11C 11/406; G06F 12/128; G06F 12/122; G06F 12/0871

(52) U.S. Cl. CPC G11C 11/40607; G06F 12/128; G06F 12/122; G06F 12/123; G06F 2212/621; G06F 2212/604; G06F 12/0871

(57) ABSTRACT

Systems and methods for selective refresh of a cache, such as a last-level cache implemented as an embedded DRAM (eDRAM). A refresh bit and a reuse bit are associated with each way of at least one set of the cache. A least recently used (LRU) stack tracks positions of the ways, with positions towards a most recently used position of a threshold comprising more recently used positions and positions towards a least recently used position of the threshold comprise less recently used positions. A line in a way is selectively refreshed if the position of the way is one of the more recently used positions and if the refresh bit associated with the way is set, or the position of the way is one of the less recently used positions and if the refresh bit and the reuse bit associated with the way are both set.

### FIELD OF DISCLOSURE

Disclosed aspects are directed to power management and efficiency improvement of memory systems. More specifically, exemplary aspects are directed to selective refresh mechanisms for dynamic random access memory (DRAM) for decreasing power consumption and increasing availability of the DRAM.

### BACKGROUND

DRAM systems provide low-cost data storage solutions because of the simplicity of their construction. Essentially, DRAM cells are made up of a switch or transistor, coupled to a capacitor. DRAM systems are organized as DRAM arrays comprising DRAM cells disposed in rows (or lines) and columns. As can be appreciated, given the simplicity of DRAM cells, the construction of DRAM systems incurs low cost and high density integration of DRAM arrays is possible. However, because capacitors are leaky, the charge stored in the DRAM cells needs to be periodically refreshed in order to correctly retain the information stored therein.

Conventional refresh operations involve reading out each DRAM cell (e.g., line by line) in a DRAM array and immediately writing back the data read out to the corresponding DRAM cells without modification, with the intent of preserving the information stored therein. Accordingly, the refresh operations consume power. Depending on specific implementations of DRAM systems (e.g., double data rate (DDR), low power DDR (LPDDR), embedded DRAM (eDRAM) etc., as known in the art) a minimum refresh frequency is defined, wherein if a DRAM cell is not refreshed at a frequency that is at least the minimum refresh frequency, then the likelihood of information stored therein becoming corrupted increases. If the DRAM cells are accessed for memory access operations such as read or write operations, the accessed DRAM cells are refreshed as part of performing the memory access operations. To ensure that the DRAM cells are being refreshed at least at a rate which satisfies the minimum refresh frequency even when the DRAM cells are not being accessed for memory access operations, various dedicated refresh mechanisms may be provided for DRAM systems.

It is recognized, however, that periodically refreshing each line of a DRAM, e.g., in an implementation of a large last level cache such as a level 3 (L3) Data Cache eDRAM, may be too expensive in terms of time and power to be feasible in conventional implementations. In an effort to mitigate the time expenses, some approaches are directed to refreshing groups of two or more lines in parallel, but these approaches may also suffer from drawbacks. For instance, if the number of lines which are refreshed at a time are relatively small, then the time consumed for refreshing the DRAM may nevertheless be prohibitively high, which may curtail availability of the DRAM for other access requests (e.g., reads/writes). This is because the ongoing refresh operations may delay or block the access requests from being serviced by the DRAM. On the other hand, if the number of lines being refreshed at a time is large, the corresponding power consumption is seen to increase, which in turn may raise demands on the robustness of power delivery networks (PDNs) used to supply power to the DRAM. A more complex PDN can also reduce routing tracks available for other wiring associated with the DRAM circuitry and increase the die size of the DRAM.

Thus, there is a recognized need in the art for improved refresh mechanisms for DRAMs which avoid the aforementioned drawbacks of conventional implementations.

### SUMMARY

Exemplary aspects of the invention are directed to systems and method for selective refresh of caches, e.g., a last-level cache of a processing system implemented as an embedded DRAM (eDRAM). The cache may be configured as a set-associative cache with at least one set and two or more ways in the at least one set and a cache controller may be provided, configured for selective refresh of lines of the at least one set. The cache controller may include two or more refresh bit registers comprising two or more refresh bits, each refresh bit associated with a corresponding one of the two or more ways and two or more reuse bit registers comprising two or more reuse bits, each reuse bit associated with a corresponding one of the two or more ways. The refresh and reuse bits are used in determining whether or not to refresh an associated line in the following manner. The cache controller may further include a least recently used (LRU) stack comprising two or more positions, each position associated with a corresponding one of the two or more ways, the two or more positions ranging from a most recently used position to a least recently used position, wherein positions towards the most recently used position of a threshold designated for the LRU stack comprise more recently used positions and positions towards the least recently used position of the threshold comprise less recently used positions. The cache controller is configured to selectively refresh a line in a way of the two or more ways if the position of the way is one of the more recently used positions and if the refresh bit associated with the way is set, or the position of the way is one of the less recently used positions and if the refresh bit and the reuse bit associated with the way are both set.

For example, an exemplary aspect is directed to a method of refreshing lines of a cache. The method comprises associating a refresh bit and a reuse bit with each of two or more ways of a set of the cache, associating a least recently used (LRU) stack with the set, wherein the LRU stack comprises a position associated with each of the two or more ways, the positions ranging from a most recently used position to a least recently used position, and designating a threshold for the LRU stack, wherein positions towards the most recently used position of the threshold comprise more recently used positions and positions towards the least recently used position of the threshold comprise less recently used positions. A line in a way of the cache is selectively refreshed if the position of the way is one of the more recently used positions and if the refresh bit associated with the way is set, or the position of the way is one of the less recently used positions and if the refresh bit and the reuse bit associated with the way are both set.

Another exemplary aspect is directed to an apparatus comprising a cache configured as a set-associative cache with at least one set and two or more ways in the at least one set and a cache controller configured for selective refresh of lines of the at least one set. The cache controller comprises two or more refresh bit registers comprising two or more refresh bits, each refresh bit associated with a corresponding one of the two or more ways, two or more reuse bit registers comprising two or more reuse bits, each reuse bit associated with a corresponding one of the two or more ways, and a least recently used (LRU) stack comprising two or more positions, each position associated with a corresponding one of the two or more ways, the two or more positions ranging from a most recently used position to a least recently used position, wherein positions towards the most recently used position of a threshold designated for the LRU stack comprise more recently used positions and positions towards the least recently used position of the threshold comprise less recently used positions. The cache controller is configured to selectively refresh a line in a way of the two or more ways if the position of the way is one of the more recently used positions and if the refresh bit associated with the way is set, or the position of the way is one of the less recently used positions and if the refresh bit and the reuse bit associated with the way are both set.

Yet another exemplary aspect is directed to an apparatus comprising a cache configured as a set-associative cache with at least one set and two or more ways in the at least one set and means for tracking positions associated with each of the two or more ways of the at least one set, the positions ranging from a most recently used position to a least recently used position, and wherein positions towards the most recently used position of the threshold comprise more recently used positions and positions towards the least recently used position of the threshold comprise less recently used positions. The apparatus further comprises means for selectively refreshing a line in a way of the cache if the position of the way is one of the more recently used positions and if a first means for indicating refresh associated with the way is set, or the position of the way is one of the less recently used positions and if the first means for indicating refresh and a second means for indicating reuse associated with the way are both set.

Another exemplary aspect is directed to a non-transitory computer-readable storage medium comprising code, which, when executed by a computer, causes the computer to perform operations for refreshing lines of a cache. The non-transitory computer-readable storage medium comprising code for associating a refresh bit and a reuse bit with each of two or more ways of a set of the cache, code for associating a least recently used (LRU) stack with the set, wherein the LRU stack comprises a position associated with each of the two or more ways, the positions ranging from a most recently used position to a least recently used position, code for designating a threshold for the LRU stack, wherein positions towards the most recently used position of the threshold comprise more recently used positions and positions towards the least recently used position of the threshold comprise less recently used positions, and code for selectively refreshing a line in a way of the cache if the position of the way is one of the more recently used positions and if the refresh bit associated with the way is set, or the position of the way is one of the less recently used positions and if the refresh bit and the reuse bit associated with the way are both set.

### BRIEF DESCRIPTION OF THE DRAWINGS

The accompanying drawings are presented to aid in the description of aspects of the invention and are provided solely for illustration of the aspects and not limitation thereof.

FIG. 1 depicts an exemplary processing system comprising a cache configured with selective refresh mechanisms, according to aspects of this disclosure.

FIGS. 2A-B illustrate aspects of dynamic threshold calculations for an exemplary cache, according to aspects of this disclosure.

FIG. 3 depicts an exemplary method refreshing a cache, according to aspects of this disclosure.

FIG. 4 depicts an exemplary computing device in which an aspect of the disclosure may be advantageously employed.

### DETAILED DESCRIPTION

Aspects of the invention are disclosed in the following description and related drawings directed to specific aspects of the invention. Alternate aspects may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any aspect described herein as “exemplary” is not necessarily to be construed as preferred or advantageous over other aspects. Likewise, the term “aspects of the invention” does not require that all aspects of the invention include the discussed feature, advantage or mode of operation.

The terminology used herein is for the purpose of describing particular aspects only and is not intended to be limiting of aspects of the invention. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In exemplary aspects of this disclosure, selective refresh mechanisms are provided for DRAMs, e.g., eDRAMs implemented in last level caches such as L3 caches. The eDRAMs may be integrated on the same system on chip (SoC) as a processor accessing the last level cache (although this is not a requirement) For such last level caches, it is recognized that a significant proportion of cache lines thereof may not receive any hits after being brought into a cache, since locality of these cache lines may be filtered at inner level caches such as level 1 (L1), level 2 (L2) caches which are closer to the processor making access requests to the caches. Further, in a set associative cache implementation of the last level caches, with cache lines organized in two or more ways in each set, it is also recognized that among the cache lines that hit in the last level caches, the corresponding hits may be confined to a subset of ways including more recently used ways a set (e.g., the 4 more recently used positions in a least recently used (LRU) stack associated with a set of the last level cache comprising 8 ways). Accordingly, the selective refresh mechanisms described herein are directed to selectively refreshing only the lines which are likely to be reused, particularly if the lines are in less recently used ways of a cache configured using DRAM technology.

In one aspect, 2 bits, referred to as a refresh bit and a reuse bit are associated with each way (e.g., by augmenting a tag associated with the way, for example, with two additional bits). Further, a threshold is designated for the LRU stack of the cache, wherein the threshold denotes a separation between more recently used lines and less recently used lines. In one aspect, the threshold may be fixed, while in another aspect, the threshold can be dynamically changed, using counters to profile the number of ways which receive hits.

In general, the refresh bit being set to “1” (or simply, being “set”) for a way is taken to indicate that a cache line stored in the associated way is to be refreshed. The reuse bit being set to “1” (or simply, being “set”) for a way is taken to indicate that the cache line in the way has seen at least one reuse. In exemplary aspects, a cache line with its refresh bit set will be refreshed while the cache line is in a way whose position is more recently used; but if the position of the way crosses the threshold to a less recently used position, then the cache line is refreshed if its refresh bit is set and its reuse bit is also set. This is because cache lines in less recently used ways are generally recognized as not likely to see a reuse and therefore are not refreshed unless their reuse bit is set to indicate that these cache lines have seen a reuse.

By selectively refreshing lines in this manner, power consumption involved in the refresh operations is reduced. Moreover, by not refreshing certain lines which may have been conventionally refreshed, the availability of the cache for other access operations, such as read/write operations, is increased.

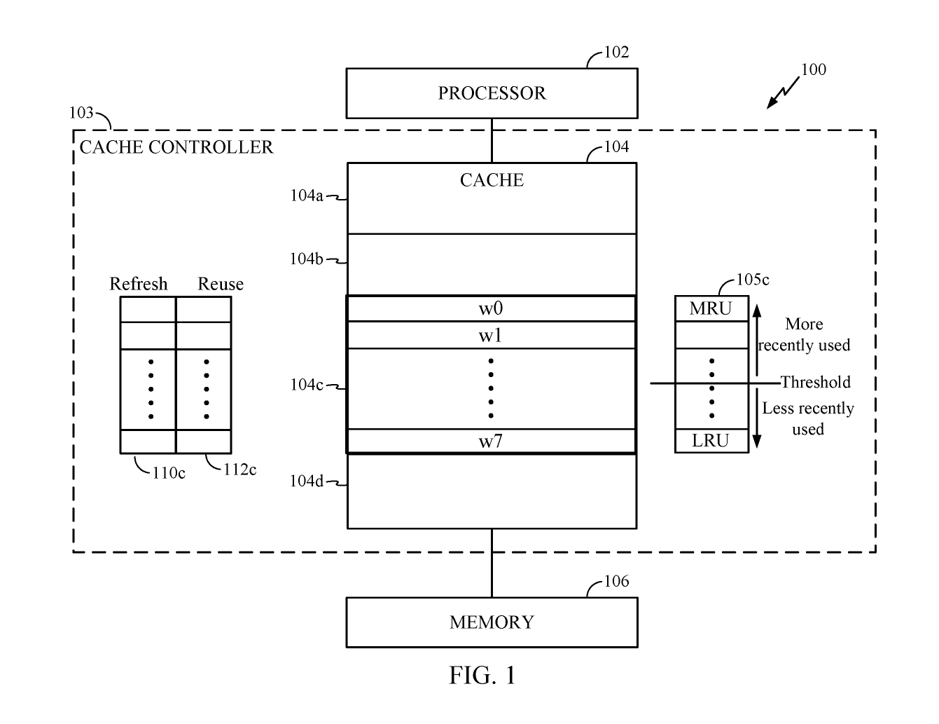

With reference first to FIG. 1, exemplary processing system 100 is illustrated with processor 102, cache 104, and memory 106 representatively shown, keeping in mind that various other components which may be present have not been illustrated for the sake of clarity. Processor 102 may be any processing element configured to make memory access requests to memory 106 which may be a main memory. Cache 104 may be one of several caches present in between processor 102 and memory 106 in a memory hierarchy of processing system 100. In one example, cache 104 may be a last-level cache (e.g., a level-3 or L3 cache), with one or more higher level caches such as level-1 (L1) caches and one or more level-2 (L2) caches present between processor 102 and cache 104, although these have not been shown. In an aspect, cache 104 may be configured as an eDRAM cache and may be integrated on the same chip as processor 102 (although this is not a requirement). Cache controller 103 has been illustrated with dashed lines to represent logic configured to perform exemplary control operations related to cache 104, including managing and implementing the selective refresh operations described herein. Although cache controller 103 has been illustrated as a wrapper around cache 104 in FIG. 1, it will be understood that the logic and/or functionality of cache controller 103 may be integrated in any other suitable manner in processing system 100, without departing from the scope of this disclosure.

As shown, in one example for the sake of illustration, cache 104 may be a set associative cache with four sets 104a-d. Each set 104a-d may have multiple ways of cache lines (also referred to as cache blocks). Eight ways w0-w7 of cache lines for set 104c have been representatively illustrated in the example of FIG. 1. Temporal locality of cache accesses may be estimated by recording an order of the cache lines in ways w0-w7 from most recently accessed or most recently used (MRU) to least recently accessed or least recently used (LRU) in stack 105c, which is also referred to as an LRU stack. LRU Stack 105c may be a buffer or an ordered collection of registers, for example, wherein each entry of LRU stack 105c may include an indication of a way, ranging from MRU to LRU (e.g., each entry of LRU stack 105c may include 3-bits to point to one of the eight ways w0-w7, such that the MRU entry may point to a first way, e.g., w5, while the LRU entry may point to a second way, e.g., w3, in an illustrative example). LRU stack 105c may be provided in or be a part of cache controller 103 in an example implementation as illustrated.

In exemplary aspects, a threshold may be used to demarcate entries of LRU stack 105c, with positions towards the most recently used (MRU) position of the threshold being referred to as more recently used positions and positions towards the less recently used (LRU) position of the threshold being referred to as less recently used positions. With such a threshold designation, the lines of LRU stack 105c in ways associated with more recently used positions may generally be refreshed, while lines in ways associated with less recently used positions may not be refreshed unless they have seen a reuse. A selective refresh in this manner is performed by using two bits to track whether a line is to be refreshed or not.

The above-mentioned two bits are representatively shown as refresh bit 110c and reuse bit 112c associated with each way w0-w7 of set 104c. Refresh bit 110c and reuse bit 112c may be configured as additional bits of a tag array (not separately shown). More generally, in alternative examples, refresh bit 110c may be stored in any memory structure such as a refresh bit register (not identified with a separate reference numeral in FIG. 1) for each way w0-w7 of set 104c and similarly, reuse bit 112c may be stored in any memory structure such as a reuse bit register (not identified with a separate reference numeral in FIG. 1) for each way w0-w7 of set 104c. Accordingly, for two or more ways w0-27 in each set, cache controller 103 may comprise a corresponding number of two or more refresh bit registers comprising refresh bits 110c and two or more reuse bit registers comprising reuse bits 112c. As previously mentioned, if refresh bit 110c is set (e.g., to value “1”) for a way of set 104c, this means that the cache line in the corresponding way is to be refreshed. If reuse bit 112c is set (e.g., to value “1”), this means that the corresponding line has seen at least one reuse.

In an exemplary aspect, cache controller 103 (or any other suitable logic) may be configured to perform exemplary refresh operations on cache 104 based on the statuses or values of refresh bit 110c and reuse bit 112c for each way, which allows selectively refreshing only lines in ways of set 104c which are likely to be reused. The description provides example functions which may be implemented in cache controller 103, for performing selective refresh operations on cache 104, and more specifically, selective refresh of lines in ways w0-w7 of set 104c of cache 104. In exemplary aspects, a line in a way is refreshed, only when the associated refresh bit 110c of the way is set and is not refreshed when the associated refresh bit 110c of the way is not set (or set to a value “0”). The following policies may be used in setting/resetting refresh bit 110c and reuse bit 112c for each line of set 104c.

When a new cache line is inserted in cache 104, e.g., in set 104c, the corresponding refresh bit 110c is set (e.g., to value “1”). The way for a newly inserted cache line will be in a more recently used position in LRU stack 105c. The position of the way starts falling from more recently used to less recently used positions as lines are inserted into other ways. Refresh bit 110c will remain set until the position associated with the way in which the line is inserted in LRU stack 105c crosses the above-noted threshold to go from a more recently used line designation to a less recently used line designation.

Once the position of the way changes to a less recently used designation, refresh bit 110c for the way is updated based on the value of reuse bit 112c. If reuse bit 112c is set (e.g., to value “1”), e.g., if the line has experienced a cache hit, then refresh bit 110c is also set and the line will be refreshed, until the line becomes stale (i.e., its reuse bit 112c is reset or set to value “0”). On the other hand, if reuse bit 112c is not set (e.g., set to value “0”), e.g., if the line has not experienced a cache hit, then refresh bit 110c is set to “0” and the line is no longer refreshed.

On a cache miss for a line in set 104c, the line may be installed in a way of set 104c and its refresh bit 110c may be set to “1” and reuse bit 112c reset or set to “0”. The relative usage of the line is tracked by the position of its way in LRU stack 105c. As previously, once the way crosses the threshold into positions designated as less recently used in LRU stack 105c, and if the line has not been reused (i.e., reuse bit 112c is “0”), then the corresponding refresh bit 110c is reset or set to “0”, to avoid refreshing stale lines which have not recently been used and may not have a high likelihood of reuse.

For a cache hit on a line in a way of set 104c, if its refresh bit 110c is set, then its reuse bit 112c is also set and the line is returned or delivered to the requestor, e.g., processor 102. In some aspects, a cache hit may be treated as a cache miss for a line in a way if refresh bit 110c is not set (or set to “0”) for that way. In further detail, a line in a way that has its refresh bit 110c not set (or set to “0”) is assumed to have exceeded a refresh limit and accordingly is treated as being stale, and so, is not returned to processor 102. The request for the cache line which is treated as a miss is then sent to a next level of backing memory, e.g., main memory 106 so a fresh and correct copy may be fetched again into cache 104.

In an aspect, if a line is in a way of set 104c which has crossed the threshold towards the MRU position into more recently used positions (e.g. the line is in the four more recently used positions) in LRU stack 105c, and if reuse bit 112c is set, then refresh bit 110c is also set, since the line has seen a reuse, and so the line is always refreshed. On the other hand, if a line crosses the threshold into more recently used positions and its reuse bit 112c is not set then refresh bit 110c is reset or set to “0”, since the line has not seen a reuse; and as such may have a low probability of future reuse; correspondingly, a refresh of the line is halted or not performed.

In some aspects, rather than a fixed threshold as described above, a dynamically variable threshold may be used in association with positions of LRU stack 105c for example set 104c of cache 104. The threshold may be dynamically changed, for example, based on program phase or some other metric.

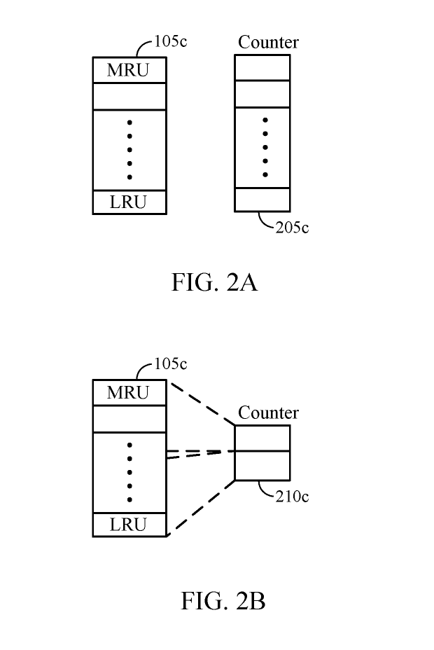

FIG. 2A illustrates one implementation of a dynamic threshold. LRU stack 105c of FIG. 1 is shown as an example, with a representative set of counters 205c, one counter associated with each way of LRU stack 105c. Counters 205c may be chosen according to implementation needs, but may generally be of size M-bits each, and set to increment each time a corresponding line of set 104c receives a hit. Thus, counters 205c may be used to profile the number of hits received by lines of set 104c. Based on values of these counters, e.g., sampled at specified intervals of time, the threshold for LRU stack 105c (based on which, a line which crosses into more recently used positions towards the MRU position may be refreshed, while lines in less recently used positions towards the LRU position may not be refreshed, as previously discussed) may be adjusted for the next sampling interval. In an example, the highest value of counters 205c is associated with the MRU position and the lowest value of counters 205c is associated with the LRU position, with values of counter 205c in between the highest and lowest values being associated with positions in between the MRU position and the LRU position, going from more recently used to less recently used designations. Thus, if a particular counter (e.g., associated with way w5) has the highest value, then a line in an associated way is refreshed until the counter value falls below that associated with the w5 position of LRU stack 105c.

In some designs, it may be desirable to reduce the hardware and/or associated resources for counters 205c of FIG. 2A. FIG. 2B illustrates another aspect wherein the resources consumed by counters for determining thresholds for LRU stack 105c may be reduced. Counters 210c shown in FIG. 2B illustrate a grouping of these counters. For instance one of the two counters 210c may be used for tracking reuse among ways w4-w7 while another one of the two counters 210c may be used for tracking reuse among ways w0-w3. In this manner, a separate counter need not be expended for each way. However, the profiling may be at a coarser granularity than may be offered by the implementation of FIG. 2A with the accompanying benefit of reduced resources. Based on the two counters 210c, decisions may be made regarding thresholds by analyzing whether the upper half or lower half of the ways of set 104c, for example, see more reuse.

In yet another implementation, although not explicitly shown, counters may be provided for only a subset of the overall number of sets of cache 104. For example, if counters N1-N4 are provided for tracking the upper half of ways of four out of 16 sets in an implementation of cache 104 (not corresponding to the illustration shown in FIG. 1), and counters M1-M4 are provided for tracking the lower half of ways of four out of 16 sets then an LRU threshold may be calculated as the maximum(avg(N1 . . . N4), avg(M1 . . . M4)).

Accordingly, it will be appreciated that exemplary aspects include various methods for performing the processes, functions and/or algorithms disclosed herein. For example, method 300 is directed to a method of refreshing lines of a cache (e.g., cache 104) as discussed further below.

In Block 302, method 300 comprises associating a refresh bit and a reuse bit with each of two or more ways of a set of the cache (e.g., associating, by cache controller 103, refresh bit 110c and reuse bit 112c with ways w0-w7 of set 104c).

Block 304 comprises associating a least recently used (LRU) stack with the set, wherein the LRU stack comprises a position associated with each of the two or more ways, the positions ranging from a most recently used position to a least recently used position (e.g., LRU stack 105c of cache controller 103 associated with set 104c, with positions ranging from MRU to LRU).

Block 306 comprises designating a threshold for the LRU stack, wherein positions towards the most recently used position of the threshold comprise more recently used positions and positions towards the least recently used position of the threshold comprise less recently used positions (e.g., a fixed threshold or a dynamic threshold, with positions towards MRU position of the threshold in LRU stack 105c shown as more recently used positions and positions towards the LRU position of the threshold shown as less recently used positions in FIG. 1, for example).

In Block 308, a line in a way of the cache may be selectively refreshed if the position of the way is one of the more recently used positions and if the refresh bit associated with the way is set; or if the position of the way is one of the less recently used positions and if the refresh bit and the reuse bit associated with the way are both set (e.g., cache controller 103 may be configured to selectively direct a refresh operation to be performed on a line in a way of the two or more ways w0-w7 of set 104c of cache 104 if the position of the way is one of the more recently used positions and if refresh bit 110c associated with the way is set; or if the position of the way is one of the less recently used positions and if refresh bit 110c and reuse bit 112c associated with the way are both set).

It will be appreciated that aspects of this disclosure also include any apparatus configured to or comprising means for performing the functionality described herein. For example, an exemplary apparatus according to one aspect comprises a cache (e.g., cache 104) configured as a set-associative cache with at least one set (e.g., set 104c) and two or more ways (e.g., ways w0-w7) in the at least one set. As such, the apparatus may comprise means for tracking positions associated with each of the two or more ways of the at least one set (e.g., LRU stack 105c), the positions ranging from a most recently used position to a least recently used position, and wherein positions towards the most recently used position of the threshold comprise more recently used positions and positions towards the least recently used position of the threshold comprise less recently used positions. The apparatus may also comprise means (e.g., cache controller 103) for selectively refreshing a line in a way of the cache if: the position of the way is one of the more recently used positions and if a first means for indicating refresh (e.g., refresh bit 110c) associated with the way is set; or the position of the way is one of the less recently used positions and if the first means for indicating refresh and a second means for indicating reuse (e.g., reuse bit 112c) associated with the way are both set.

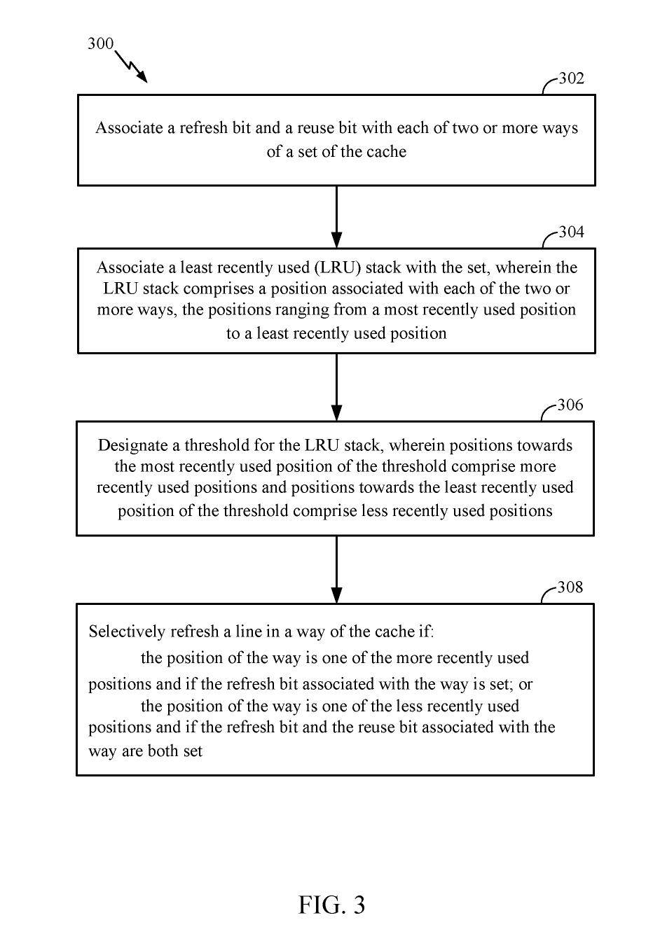

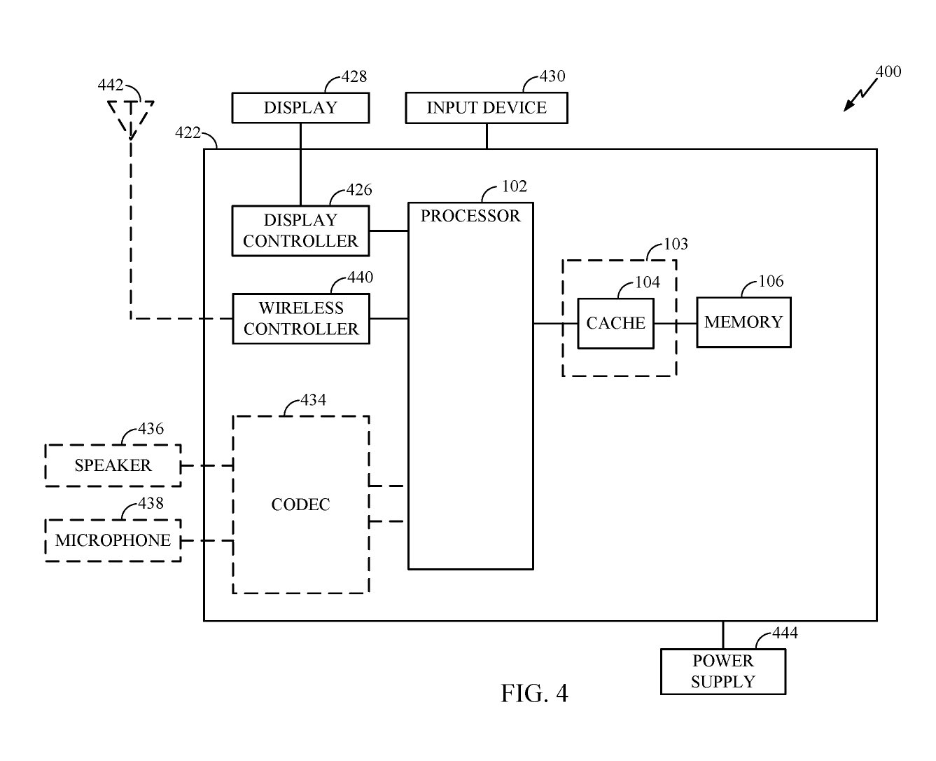

An example apparatus in which exemplary aspects of this disclosure may be utilized, will now be discussed in relation to FIG. 4. FIG. 4 shows a block diagram of computing device 400. Computing device 400 may correspond to an exemplary implementation of a processing system configured to perform method 300 of FIG. 3. In the depiction of FIG. 4, computing device 400 is shown to include processor 102 and cache 104, along with cache controller 103 shown in FIG. 1. Cache controller 103 is configured to perform the selective refresh mechanisms on cache 104 as discussed herein (although further details of cache 104 such as sets 104a-d, ways w0-w7 as well as further details of cache controller 103 such as refresh bits 110c, reuse bits 112c, LRU stack 105c, etc. which were shown in FIG. 1 have been omitted from this view for the sake of clarity). In FIG. 4, processor 102 is exemplarily shown to be coupled to memory 106 with cache 104 between processor 102 and memory 106 as described with reference to FIG. 1, but it will be understood that other memory configurations known in the art may also be supported by computing device 400.

FIG. 4 also shows display controller 426 that is coupled to processor 102 and to display 428. In some cases, computing device 400 may be used for wireless communication and FIG. 4 also shows optional blocks in dashed lines, such as coder/decoder (CODEC) 434 (e.g., an audio and/or voice CODEC) coupled to processor 102 and speaker 436 and microphone 438 can be coupled to CODEC 434; and wireless antenna 442 coupled to wireless controller 440 which is coupled to processor 102. Where one or more of these optional blocks are present, in a particular aspect, processor 102, display controller 426, memory 106, and wireless controller 440 are included in a system-in-package or system-on-chip device 422.

Accordingly, in a particular aspect, input device 430 and power supply 444 are coupled to the system-on-chip device 422. Moreover, in a particular aspect, as illustrated in FIG. 4, where one or more optional blocks are present, display 428, input device 430, speaker 436, microphone 438, wireless antenna 442, and power supply 444 are external to the system-on-chip device 422. However, each of display 428, input device 430, speaker 436, microphone 438, wireless antenna 442, and power supply 444 can be coupled to a component of the system-on-chip device 422, such as an interface or a controller.

It should be noted that although FIG. 4 generally depicts a computing device, processor 102 and memory 106, may also be integrated into a set top box, a server, a music player, a video player, an entertainment unit, a navigation device, a personal digital assistant (PDA), a fixed location data unit, a computer, a laptop, a tablet, a communications device, a mobile phone, or other similar devices.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an aspect of the invention can include computer-readable media embodying a method for selective refresh of a DRAM. Accordingly, the invention is not limited to illustrated examples and any means for performing the functionality described herein are included in aspects of the invention.

While the foregoing disclosure shows illustrative aspects of the invention, it should be noted that various changes and modifications could be made herein without departing from the scope of the invention as defined by the appended claims. The functions, steps and/or actions of the method claims in accordance with the aspects of the invention described herein need not be performed in any particular order. Furthermore, although elements of the invention may be described or claimed in the singular, the plural is contemplated unless limitation to the singular is explicitly stated.

What is claimed is:

1. A method of refreshing lines of a cache, the method comprising:
associating a refresh bit and a reuse bit with each of two or more ways of a set of the cache;
associating a least recently used (LRU) stack with the set, wherein the LRU stack comprises a position associated with each of the two or more ways, the positions ranging from a most recently used position to a least recently used position;
designating a threshold for the LRU stack, wherein positions towards the most recently used position of the threshold comprise more recently used positions and positions towards the least recently used position of the threshold comprise less recently used positions; and
selectively refreshing a line in a way of the cache if:
the position of the way is one of the more recently used positions and if the refresh bit associated with the way is set; or
the position of the way is one of the less recently used positions and if the refresh bit and the reuse bit associated with the way are both set.

2. The method of claim 1, wherein when the line is newly inserted into the way upon a miss in the cache for the line:
associating the position of the way with one of the more recently used positions;
setting the refresh bit; and
resetting the reuse bit.

3. The method of claim 2, further comprising when the position of the way crosses the threshold and the position of the way is one of the less recently used positions,
retaining the refresh bit as being set if the reuse bit is set; or
resetting the refresh bit if the reuse bit of is not set.

4. The method of claim 2, further comprising, upon a hit in the cache for the line, setting the reuse bit.

5. The method of claim 1, further comprising, upon a cache hit for the line, returning the line to a requester of the line from the cache if the refresh bit is set and the reuse bit is also set.

6. The method of claim 1, further comprising, upon a cache hit for the line, treating the cache hit as a cache miss if the refresh bit is not set and forwarding a request for the line to a backing memory of the cache.

7. The method of claim 1, wherein if the position of the way crosses the threshold from one of the less recently used positions to one of the more recently used positions and the reuse bit is set, then setting the refresh bit.

8. The method of claim 1, wherein if the position of the way crosses the threshold from one of the less recently used positions to one of the more recently used positions and the reuse bit is not set, then resetting the refresh bit.

9. The method of claim 1, wherein the threshold is fixed with respect to the positions of the LRU stack.

10. The method of claim 1, wherein the threshold is dynamically variable based on values of counters associated with the LRU stack, wherein the counters associated with ways which have a cache hit are incremented.

11. The method of claim 10, wherein a counter is common to two or more ways.

12. The method of claim 1, wherein the cache is implemented as an embedded DRAM (eDRAM).

13. The method of claim 1, wherein the cache is configured as a last-level cache of a processing system.

14. An apparatus comprising:
a cache configured as a set-associative cache with at least one set and two or more ways in the at least one set;
a cache controller configured for selective refresh of lines of the at least one set, the cache controller comprising:
two or more refresh bit registers comprising two or more refresh bits, each refresh bit associated with a corresponding one of the two or more ways;
two or more reuse bit registers comprising two or more reuse bits, each reuse bit associated with a corresponding one of the two or more ways; and
a least recently used (LRU) stack comprising two or more positions, each position associated with a corresponding one of the two or more ways, the two or more positions ranging from a most recently used position to a least recently used position,
wherein positions towards the most recently used position of a threshold designated for the LRU stack comprise more recently used positions and positions towards the least recently used position of the threshold comprise less recently used positions; and
wherein the cache controller is configured to selectively refreshing a line in a way of the two or more ways if:
the position of the way is one of the more recently used positions and if the refresh bit associated with the way is set; or
the position of the way is one of the less recently used positions and if the refresh bit and the reuse bit associated with the way are both set.

15. The apparatus of claim 14, wherein the cache controller is further configured to, when the line is newly inserted into the way upon a miss in the cache for the line:
associate the position of the way with one of the more recently used positions;
set the refresh bit; and
reset the reuse bit.

16. The apparatus of claim 15, wherein the cache controller is further configured to, when the position of the way crosses the threshold and the position of the way is one of the less recently used positions:
retain the refresh bit as being set if the reuse bit is set; or
reset the refresh bit if the reuse bit of is not set.

17. The apparatus of claim 15, wherein the cache controller is further configured to, upon a hit in the cache for the line, set the reuse bit.

18. The apparatus of claim 14, wherein the cache controller is further configured to, upon a cache hit for the line, return the line to a requester of the line from the cache if the refresh bit is set and the reuse bit is also set.

19. The apparatus of claim 14, wherein the cache controller is further configured to, upon a cache hit for the line, treat the cache hit as a cache miss if the refresh bit is not set and forward a request for the line to a backing memory of the cache.

20. The apparatus of claim 14, wherein the cache controller is further configured to, if the position of the way crosses the threshold from one of the less recently used positions to one of the more recently used positions and the reuse bit is set, then set the refresh bit.

21. The apparatus of claim 14, wherein the cache controller is further configured to, if the position of the way crosses the threshold from one of the less recently used positions to one of the more recently used positions and the reuse bit is not set, then reset the refresh bit.

22. The apparatus of claim 14, wherein the threshold is fixed with respect to the positions of the LRU stack.

23. The apparatus of claim 14, wherein the cache controller further comprises counters associated with the LRU stack, and wherein the threshold is dynamically variable based on values of the counters, and wherein the counters associated with ways which have a cache hit are incremented.

24. The apparatus of claim 23, wherein a counter is common to two or more ways.

25. The apparatus of claim 14, wherein the cache is implemented as an embedded DRAM (eDRAM).

26. The apparatus of claim 14 comprising a processing system, wherein the cache is configured as a last-level cache of the processing system.

27. The apparatus of claim 14 integrated into a device selected from the group consisting of a set top box, a server, a music player, a video player, an entertainment unit, a navigation device, a personal digital assistant (PDA), a fixed location data unit, a computer, a laptop, a tablet, a communications device, and a mobile phone.

28. An apparatus comprising:
a cache configured as a set-associative cache with at least one set and two or more ways in the at least one set;
means for tracking positions associated with each of the two or more ways of the at least one set, the positions ranging from a most recently used position to a least recently used position, and wherein positions towards the most recently used position of a threshold comprise more recently used positions and positions towards the least recently used position of the threshold comprise less recently used positions; and
means for selectively refreshing a line in a way of the cache if:
the position of the way is one of the more recently used positions and if a first means for indicating refresh associated with the way is set; or
the position of the way is one of the less recently used positions and if the first means for indicating refresh and a second means for indicating reuse associated with the way are both set.

29. A non-transitory computer-readable storage medium comprising code, which, when executed by a computer, causes the computer to perform operations for refreshing lines of a cache, the non-transitory computer-readable storage medium comprising:
code for associating a refresh bit and a reuse bit with each of two or more ways of a set of the cache;
code for associating a least recently used (LRU) stack with the set, wherein the LRU stack comprises a position associated with each of the two or more ways, the positions ranging from a most recently used position to a least recently used position;
code for designating a threshold for the LRU stack, wherein positions towards the most recently used position of the threshold comprise more recently used positions and positions towards the least recently used position of the threshold comprise less recently used positions; and
code for selectively refreshing a line in a way of the cache if:
the position of the way is one of the more recently used positions and if the refresh bit associated with the way is set; or
the position of the way is one of the less recently used positions and if the refresh bit and the reuse bit associated with the way are both set.

30. The non-transitory computer-readable storage medium of claim 29, further comprising, when the line is newly inserted into the way upon a miss in the cache for the line:
code for associating the position of the way with one of the more recently used positions;
code for setting the refresh bit; and
code for resetting the reuse bit.
